(19) United States
(12) Patent Application Publication
(10) Pub. No.: US 2006/0250772 A1
(43) Pub. Date: Nov. 9, 2006

(54) Liquid DIMM Cooler

(75) Inventors: Richard Salmonson, Chippewa Falls, WI (US); Scott Robinson, Chippewa Falls, WI (US); Timothy McCann, Eleva, WI (US); David Collins, Eau Claire, WI (US)

Correspondence Address: BROMBERG & SUNSTEIN LLP, 125 SUMMER STREET, BOSTON, MA, 02110-1618, US

(73) Assignee: Silicon Graphics, Inc., Mountain View, CA (US)

(21) Appl. No.: 11/121,975

(22) Filed: May 4, 2005

(51) Int. Cl. H05K 7/20

(52) U.S. Cl. 361/698

(57) ABSTRACT

A liquid cooled heat sink for electronic circuit boards is described. A heat sink base includes a liquid cooling arrangement to remove heat from the base. An arrangement of cooling fins extends from the base, and at least one surface of each fin includes a thermal interface layer. The arrangement is adapted so that the fins fit between parallel electronic circuit boards such that for each circuit board, a thermal contact layer of a fin contacts multiple components on the circuit board so as to conduct heat from the components into the fin, which in turn transfers heat to the heat sink base.

### FIELD OF THE INVENTION

The invention generally relates to cooling of electronic components, and specifically to a liquid cooling arrangement for electronic circuit boards.

### BACKGROUND ART

Computer vendors continue to package more powerful components within their computer systems. One aspect of using more power is the creation of heat, which can degrade operation of the components. In the past, heat has been removed mainly by air cooling, either using natural circulation or fan-driven forced flow arrangements, sometimes in conjunction with fin-based heat sinks attached to the heat generating components. One problem with such arrangements is that components are limited to being laid out with an optimal orientation with respect to the air flow and specific component density restrictions must not be exceeded.

At the same time, use of standard commodity components, where possible, is a top priority to minimize system cost. For example, many companies use industry standard dual in-line memory modules (DIMMs) in their computer systems. A DIMM is a small electronic circuit board that holds memory chips. The historical predecessor to the DIMM was the single in-line memory module (SIMM). One common DIMM-type has 168 pins and a uses a 64-bit data path, which is twice the size of the SIMM (72 pins, 32-bit). When using a 64-bit processor such as an Intel Pentium™, SIMMs must be installed two at a time, whereas 64-bit DIMMs can be installed one module at a time. Industry standard DIMMs have been air cooled since they were introduced.

FIG. 1 shows a typical computer system motherboard 10 containing various components and modules that generate heat. The identity, number, and arrangement of the components shown in this and all the other figures are only examples and do not limit the scope of the invention in any manner. In addition to microprocessor 11 (e.g., an Intel Pentium 4 processor), a typical motherboard might include some or all of chipset 12 containing memory controller hub (MCH) devices. An accelerated graphics port (AGP) 19 allows for mounting a graphic module, and six PCI ports 14 are provided to install expansion modules. Similarly, a parallel port 15 and a game connect port 16 are defined on the edge of the motherboard 10. The motherboard 10 also has IDE slots 17 adjacent to the DIMM sockets 13 to connect a hard disk memory, CD-ROM device, and other peripheral devices through bus lines. Another FDD slot 18 is defined adjacent to the IDE slots 17 to connect to a soft disk through bus lines.

The motherboard 10 in FIG. 1 also includes three DIMM sockets 13 allowing the mounting of typical DIMM devices, such as for Synchronous Dynamic Random Access Memory (SDRAM). The standard arrangement of such DIMM sockets 13 results in the DIMM modules being perpendicular to the motherboard 10 and parallel to each other. Specific motherboards may support fewer or more than three DIMM sockets.

U.S. Pat. No. 6,366,461 describes an arrangement for cooling electronic components on a computer system motherboard. Some of the disclosed components, such as the processor, are liquid cooled, while other components, such as the DIMM modules, are air cooled.

### SUMMARY OF THE INVENTION

Embodiments of the present invention include a heat sink for electronic circuit boards. A heat sink base includes a liquid cooling arrangement to remove heat from the base. An arrangement of cooling fins extends from the base, and at least one surface of each fin includes a thermal interface layer. The arrangement is adapted so that the fins fit between parallel electronic circuit boards such that for each circuit board, a thermal contact layer of a fin contacts multiple components on the circuit board so as to conduct heat from the components into the fin, which in turn transfers heat to the heat sink base.

In further embodiments, the cooling fins extend perpendicularly from the heat sink base. The heat sink base, or the cooling fins, or both may be made of aluminum, copper, or any other thermally conductive material. The electronic circuit boards may be a DIMM modules and/or may include at least one of a Voltage Regulator (VR) module, a graphics module, an input/output (I/O) module, or a PCI module. The thermal interface layer may include an outer layer of electrically isolating material. The heat sink may also include securing hardware to mechanically attach the heat sink in place against shock and vibration loads that result from handling and transporting.

### BRIEF DESCRIPTION OF THE DRAWINGS

FIG. 1 shows a typical computer system motherboard containing heat generating components.

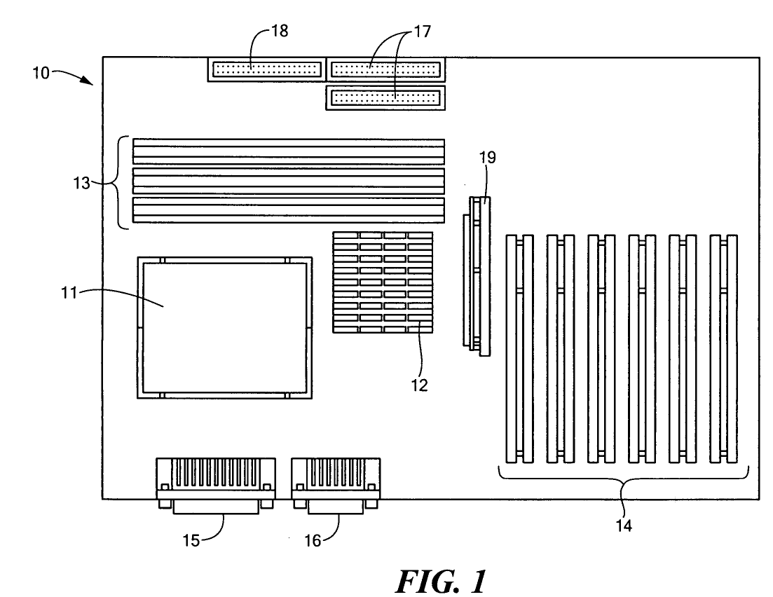

FIG. 2 shows a side view of a liquid cooled heat sink arrangement according to one embodiment.

FIG. 3 shows an elevated perspective side view of a liquid cooled heat sink arrangement as in FIG. 2.

### DETAILED DESCRIPTION OF SPECIFIC EMBODIMENTS

As computer system power levels have continued to rise, liquid cooling arrangements have been used for various computer system modules and components, including ASIC packages, microprocessors, and power supplies. However, applicants are unaware of any such method to provide liquid cooling to standard form factor DIMM modules.

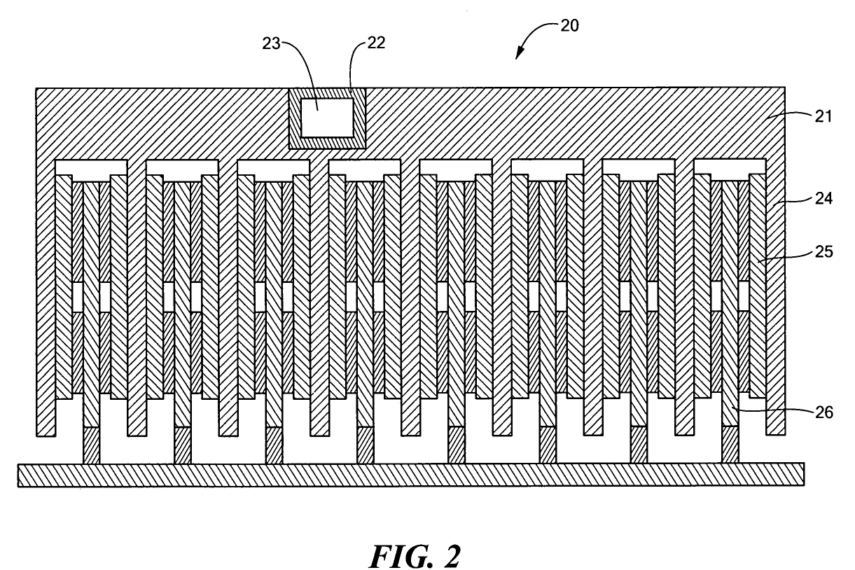

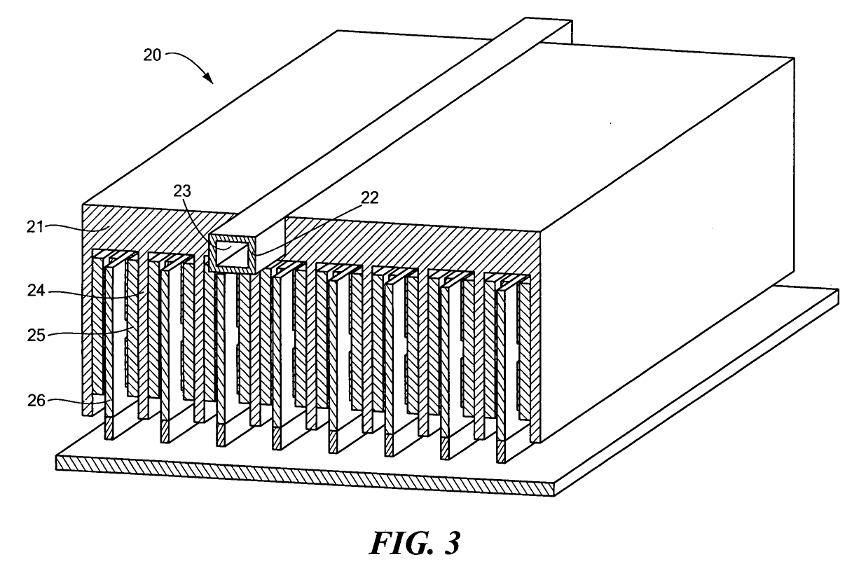

According to embodiments of the present invention, a liquid cooling arrangement cools standard form factor DIMMs. FIG. 2 shows a side view and FIG. 3 shows an elevated perspective side view of a liquid cooled heat sink arrangement according to one embodiment. Motherboard 10 has an arrangement of multiple DIMMs 26 that are perpendicular to the board and parallel to each other. Embodiments of the invention are also applicable to other electronic circuit modules that may be connected perpendicularly or at an angle to the motherboard 10, including without limitation Voltage Regulator (VR) modules, graphics modules, input/output (I/O) modules, or any standard PCI module.

As known by those in the art, the DIMMs 26 generate heat that needs to be removed. Accordingly, a heat sink arrangement 20 is positioned above and between the DIMMs 26. Heat sink base 21 may be a solid block of thermally conducting material, e.g., aluminum, copper, or any other thermally conductive material. Cooling fins 24 extend downwardly from the heat sink base 21 and between the DIMMs 26. The cooling fins 24 may also be made of heat conducting material, such as aluminum, copper, etc. When the heat sink 20 is lowered over the DIMMs 26, the cooling fins 24 pass in-between the DIMMs 26.

The surfaces of the fins include a thermal interface layer 25 made of a soft heat conducting material arranged to gently contact the components on DIMMs 26 but still provide enough contact pressure to allow for adequate thermal transfer. For example, the thermal interface layer may be made of Gap Pad V0 Ultra Soft thermal pad by the Bergquist Company is a compressible silicone thermal interface material which is available in a range of 0.020″ to 0.200″ thick, and which has silicone/fiberglass cloth on one side that avoids tearing when the cooling fins 24 sliding on over the components on DIMMs 26.

Heat generated by the DIMMs 26 is conducted through the thermal interface layer 25 into the cooling fins 24, and thereby into the heat sink base 21. The heat sink base 21 also includes one or more liquid cooling tubes 22 containing circulating cooling liquid 23. Thus, this liquid 23 circulating in the cooling tube 22 removes heat conducted by the cooling fins 24 into the heat sink base 21. Cooling tube 22 may be simply a copper or aluminum tube that is pressed into pressed in place in heat sink base 21. The geometry of the cooling tube 22 may be any of various convenient shapes to provide the desired heat transfer from the heat sink base 21 to the liquid 23 circulating in the cooling tube 22. The liquid 23 may water or any other liquid with desirable heat capacity.

In some embodiments, the thermal interface material 25 may include a thin outer layer of electrically isolating material to avoid creating shorting issues with respect to the components on the DIMMs 26. In such an embodiment, the electrical characteristics of the thermal interface material 25 may be unimportant. The electrical isolating material may also provide some protection to the thermal interface material 25 from the projections of the components on the DIMMs 26 by preventing the thermal interface material 25 from catching the side of a board component and damaging either the thermal interface material 25 or the board component as the cooling fin 24 passes by when the heat sink 20 is installed over an arrangement of DIMMs 26. In other embodiments, the thermal interface material 25 is itself electrically isolating (i.e., non-conductive) and an electrically isolating outer layer may not be needed. The heat sink arrangement 20 may be secured to the motherboard 10 using mechanical hardware to prevent movement or shifting such as may occur, for example, during shipping of a computer system.

Although various exemplary embodiments of the invention have been disclosed, it should be apparent to those skilled in the art that various changes and modifications can be made which will achieve some of the advantages of the invention without departing from the true scope of the invention.

What is claimed is:

1. A heat sink for electronic circuit boards, the heat sink comprising:
a heat sink base including a liquid cooling arrangement to remove heat from the base; and
an arrangement of cooling fins extending from the base, at least one surface of each fin including a thermal interface layer;
wherein the arrangement is adapted so that the fins fit between parallel electronic circuit boards such that for each circuit board, a thermal contact layer of a fin contacts a plurality of components on the circuit board so as to conduct heat from the components into the fin, which in turn transfers heat to the heat sink base.

2. A heat sink according to claim 1, wherein the cooling fins extend perpendicularly from the heat sink base.

3. A heat sink according to claim 1, wherein the heat sink base is made of aluminum.

4. A heat sink according to claim 1, wherein the heat sink base is made of copper.

5. A heat sink according to claim 1, wherein the cooling fins are made of aluminum.

6. A heat sink according to claim 1, wherein the cooling fins are made of copper.

7. A heat sink according to claim 1, wherein the electronic circuit boards are DIMM modules.

8. A heat sink according to claim 1, wherein the electronic circuit boards include at least one of a Voltage Regulator (VR) module, a graphics module, an input/output (I/O) module, or a PCI module.

9. A heat sink according to claim 1, wherein the thermal interface layer includes an outer layer of electrically isolating material.

10. A heat sink according to claim 1, further comprising:
securing hardware to mechanically attach the heat sink in place.

11. A method of liquid cooling for electronic circuit boards, the method comprising:
providing a heat sink base including a liquid cooling arrangement to remove heat from the base; and
providing an arrangement of cooling fins extending from the base, at least one surface of each fin including a thermal interface layer;
wherein the arrangement is adapted so that the fins fit between parallel electronic circuit boards such that for each circuit board, a thermal contact layer of a fin contacts a plurality of components on the circuit board so as to conduct heat from the components into the fin, which in turn transfers heat to the method base.

12. A method according to claim 11, wherein the cooling fins extend perpendicularly from the method base.

13. A method according to claim 11, wherein the heat sink base is made of aluminum.

14. A method according to claim 11, wherein the heat sink base is made of copper.

15. A method according to claim 11 wherein the cooling fins are made of aluminum.

16. A method according to claim 11 wherein the cooling fins are made of copper.

17. A method according to claim 11, wherein the electronic circuit boards are DIMM modules.

18. A method according to claim 11, wherein the electronic circuit boards include at least one of a Voltage Regulator (VR) module, a graphics module, an input/output (I/O) module, or a PCI module.

19. A method according to claim 11, wherein the thermal interface layer includes an outer layer of electrically isolating material.

20. A method according to claim 11, further comprising:
providing securing hardware to mechanically attach the heat sink in place.
